(19) United States
(12) Patent Application Publication
(10) Pub. No.: US 2025/0215561 A1
(43) Pub. Date: Jul. 3, 2025

(54) Substrate Processing Apparatus, Heat Insulating Structure, Method of Manufacturing Semiconductor Device and Non-transitory Computer-readable Recording Medium

(71) Applicant: Kokusai Electric Corporation, Tokyo (JP)

(72) Inventor: Yusaku OKAJIMA, Toyama (JP)

(21) Appl. No.: 19/086,411

(22) Filed: Mar. 21, 2025

Related U.S. Application Data
(63) Continuation of application No. PCT/JP2022/035239, filed on Sep. 21, 2022.

(51) Int. Cl. C23C 16/44; C23C 16/455; C23C 16/458; H01L 21/02

(52) U.S. Cl. CPC C23C 16/4408; C23C 16/4412; C23C 16/45521; C23C 16/4585; H01L 21/0217; H01L 21/02271

(57) ABSTRACT

It is possible to reduce a flow rate of a purge gas for purging an inside of a heat insulating structure. There is provided a technique that includes: a process chamber in which a substrate is processed; a substrate support configured to support the substrate; and a heat insulating structure provided below the substrate support and including: a vessel configured such that a horizontal cross-sectional area of an upper part of an inner space of the vessel is greater than that of a lower part of the inner space of the vessel; a first inert gas supplier configured to be capable of supplying an inert gas into the vessel; and an opening through which an inside and an outside of the vessel is capable of communicating with each other.

### CROSS REFERENCE TO RELATED APPLICATIONS

This application is a bypass continuation application of PCT International Application No. PCT/JP2022/035239, filed on Sep. 21, 2022, in the WIPO, the entire contents of which are hereby incorporated by reference.

### TECHNICAL FIELD

The present disclosure relates to a substrate processing apparatus, a heat insulating structure, a method of manufacturing a semiconductor device and a non-transitory computer-readable recording medium.

### BACKGROUND

In a substrate processing apparatus according to some related arts, a shaft purge gas may be supplied to an upper portion inside a heat insulating assembly and exhausted to an outside of the heat insulating assembly through an exhaust hole.

### SUMMARY

According to the present disclosure, there is provided a technique capable of reducing a flow rate of a purge gas for purging an inside of a heat insulating structure.

According to an embodiment of the present disclosure, there is provided a technique that includes: a process chamber in which a substrate is processed; a substrate support configured to support the substrate; and a heat insulating structure provided below the substrate support and including: a vessel configured such that a horizontal cross-sectional area of an upper part of an inner space of the vessel is greater than that of a lower part of the inner space of the vessel; a first inert gas supplier configured to be capable of supplying an inert gas into the vessel; and an opening through which an inside and an outside of the vessel is capable of communicating with each other.

### BRIEF DESCRIPTION OF THE DRAWINGS

FIG. 1 is a diagram schematically illustrating a vertical cross-section of a substrate processing apparatus according to a first embodiment of the present disclosure.

FIG. 2A is a diagram schematically illustrating a first gas supplier according to the first embodiment of the present disclosure, FIG. 2B is a diagram schematically illustrating a second gas supplier according to the first embodiment of the present disclosure, FIG. 2C is a diagram schematically illustrating a first inert gas supplier according to the first embodiment of the present disclosure, and FIG. 2D is a diagram schematically illustrating a second inert gas supplier according to the first embodiment of the present disclosure.

FIG. 3 is a diagram schematically illustrating a heat insulating structure and a periphery thereof according to the first embodiment of the present disclosure.

FIG. 4 is a block diagram schematically illustrating a configuration of a controller and related components of the substrate processing apparatus according to the first embodiment of the present disclosure.

FIG. 5 is a flow chart schematically illustrating a substrate processing flow according to the first embodiment of the present disclosure.

FIG. 6 is a flow chart schematically illustrating a film processing step shown in FIG. 5.

FIG. 7 is a diagram schematically illustrating a heat insulating structure and a periphery thereof according to a second embodiment of the present disclosure.

FIG. 8 is a diagram schematically illustrating a heat insulating structure and a periphery thereof according to a third embodiment of the present disclosure.

FIG. 9 is a diagram schematically illustrating a heat insulating structure and a periphery thereof according to a fourth embodiment of the present disclosure.

### DETAILED DESCRIPTION

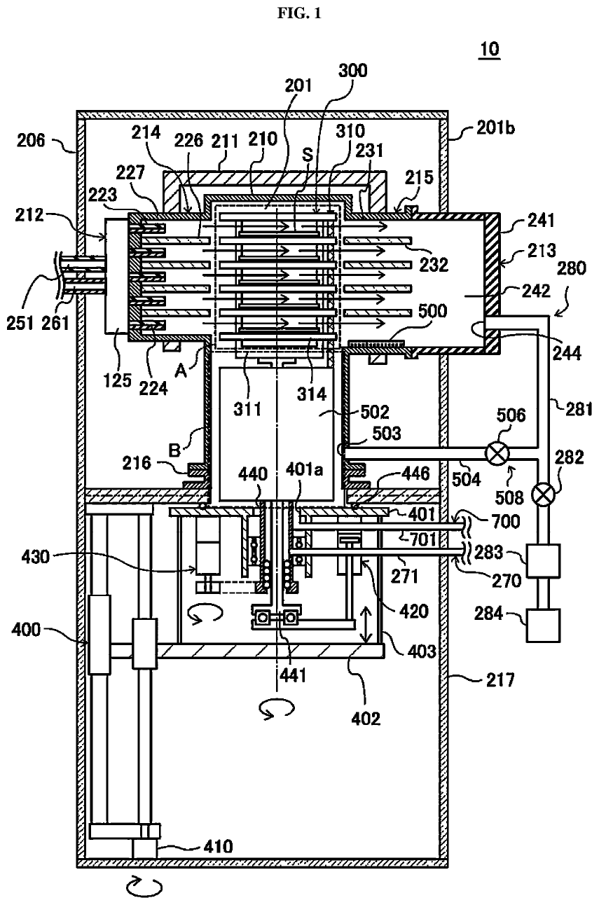

Hereinafter, one or more embodiments (also simply referred to as “embodiments”) according to the technique of the present disclosure will be described with reference to FIGS. 1 to 9. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

First, a first embodiment according to the technique of the present disclosure will be described. A configuration of a substrate processing apparatus 10 according to the present embodiment will be described with reference to FIG. 1.

The substrate processing apparatus 10 includes a reaction tube storage chamber 206. In the reaction tube storage chamber 206, a reaction tube 210 of a cylindrical shape extending in a vertical direction, a heater 211 serving as a heating structure (furnace body) installed on an outer periphery of the reaction tube 210, a gas supply structure 212 serving as a part of a process gas supplier (which is a process gas supply system), and a gas exhaust structure 213 serving as a part of a process gas exhauster (which is a process gas exhaust system) are provided. The process gas supplier may further include an upstream side gas guide 214 or nozzles 223 and 224, which will be described later. Further, the process gas exhauster may further include a downstream side gas guide 215, which will be described later.

The gas supply structure 212 is provided upstream in a gas flow direction and beside the reaction tube 210. A gas such as a process gas is supplied into a process chamber 201 in the reaction tube 210 through the gas supply structure 212. Then, the gas is supplied to a substrate S in a horizontal direction. The gas exhaust structure 213 is provided downstream in the gas flow direction and beside the reaction tube 210, and the gas in the reaction tube 210 is discharged (exhausted) through the gas exhaust structure 213. The gas exhaust structure 213 is disposed opposite to the gas supply structure 212 with the reaction tube 210 interposed therebetween.

The process chamber 201 includes the reaction tube 210 into which the substrate S is transferred (loaded), the gas supply structure 212 and the gas exhaust structure 213. A plurality of substrates including the substrate S are processed in the process chamber 201. Hereinafter, the plurality of substrates including the substrate S may also be referred to as “substrates S.” In addition, the gas supply structure 212, an inside of the reaction tube 210 and the gas exhaust structure 213 communicate with one another in the horizontal direction.

On an upstream side of the reaction tube 210 between the reaction tube 210 and the gas supply structure 212, the upstream side gas guide 214 configured to adjust a flow of the gas supplied through the gas supply structure 212 is provided. In addition, on a downstream side of the reaction tube 210 between the reaction tube 210 and the gas exhaust structure 213, the downstream side gas guide 215 configured to adjust the flow of the gas discharged from the reaction tube 210 is provided. A lower end of the reaction tube 210 is supported by a manifold 216.

The reaction tube 210, the upstream side gas guide 214 and the downstream side gas guide 215 are implemented as a continuous structure. For example, each of the reaction tube 210, the upstream side gas guide 214 and the downstream side gas guide 215 is made of a material such as quartz and silicon carbide (SiC). In addition, each of the reaction tube 210, the upstream side gas guide 214 and the downstream side gas guide 215 is constituted by a heat transmittable structure capable of transmitting a heat radiated from the heater 211. The heat of the heater 211 can heat the substrate S and the gas. In addition, the heater 211 is disposed beside the process chamber 201 such that the heater 211 is configured to be capable of heating the process chamber 201.

The gas supply structure 212 is connected to each of a gas supply pipe 251 and a gas supply pipe 261. In addition, the gas supply structure 212 includes a distributor (which is a distribution structure) 125 configured to distribute gases supplied through each gas supply pipe mentioned above. A plurality of nozzles including the nozzle 223 and a plurality of nozzles including the nozzle 224 are provided at a downstream side of the distributor 125. Hereafter, the plurality of nozzles including the nozzle 223 may also be simply referred to as “nozzles 223”, and the plurality of nozzles including the nozzle 224 may also be simply referred to as “nozzles 224”. The nozzle 223 and the nozzle 224 are connected to a downstream side of the gas supply pipe 251 and a downstream side of the gas supply pipe 261, respectively, via the distributor 125. The nozzles 223 and the nozzles 224 are arranged side by side substantially in the horizontal direction. In addition, the nozzles 223 and the nozzles 224 are arranged in the vertical direction at positions corresponding to the substrates S. The process gas is supplied from beside the substrate S while the substrate S is in the process chamber 201.

The distributor 125 is configured such that each gas can be supplied to the nozzles 223 through the gas supply pipe 251 and to the nozzles 224 through the gas supply pipe 261. For example, a gas flow path can be provided for each combination of the gas supply pipe and the nozzle corresponding to the gas supply pipe. Thereby, since the gases respectively supplied through the gas supply pipes mentioned above are not mixed, it is possible to suppress a generation of reaction by-products (also referred to as “particles”) that may be generated when the gases are mixed in the distributor 125.

The upstream side gas guide 214 includes a housing 227 and a partition plate 226. The partition plate 226 extends in the horizontal direction. The “horizontal direction” of the partition plate 226 may refer to a direction toward a side wall of the housing 227. A plurality of partition plates including the partition plate 226 are arranged in the vertical direction. Hereafter, the plurality of partition plates including the partition plate 226 may also be simply referred to as “partition plates 226”. The partition plate 226 is fixed to the side wall of the housing 227 such that it is possible to prevent the gas from flowing beyond the partition plate 226 into an adjacent region below or above the partition plate 226. By preventing the gas from flowing beyond the partition plate 226, it is possible to reliably form a flow of the gas (also referred to as a “gas flow”) described later.

The partition plates 226 are provided at positions corresponding to the substrates S, respectively. The nozzle 223 and the nozzle 224 are arranged between adjacent partition plates 226 or between the housing 227 and an uppermost or lowermost partition plate among the partition plates 226.

The gas ejected through the nozzle 223 or the nozzle 224 is supplied to a surface of the substrate S. That is, when viewed from the substrate S, the gas is supplied along a lateral direction of the substrate S. Since the partition plate 226 is a continuous structure extending in the horizontal direction and provided without a hole, a mainstream of the gas is restrained from flowing in the vertical direction and flows in the horizontal direction. Therefore, a pressure loss of the gas reaching each substrate S can be uniformized along the vertical direction.

The downstream side gas guide 215 is configured such that a ceiling thereof is provided above an uppermost substrate among the substrates S supported by a substrate support structure 300 described later, and a bottom thereof is provided below a lowermost substrate among the substrates S supported by the substrate support structure 300. The substrate support structure 300 is used as a substrate retainer (or a substrate support) capable of holding (or supporting) the substrates S.

The downstream side gas guide 215 includes a housing 231 and a partition plate 232. The partition plate 232 extends in the horizontal direction. The “horizontal direction” of the partition plate 232 may refer to a direction toward a side wall of the housing 231. Further, a plurality of partition plates including the partition plate 232 are arranged in the vertical direction. Hereafter, the plurality of partition plates including the partition plate 232 may also be simply referred to as “partition plates 232”. The partition plate 232 is fixed to the side wall of the housing 231 such that it is possible to prevent the gas from flowing beyond the partition plate 232 into an adjacent region below or above the partition plate 232. By preventing the gas from flowing beyond the partition plate 232, it is possible to reliably form the gas flow described later.

The upstream side gas guide 214 communicates with a space within the downstream side gas guide 215 via the process chamber 201. A ceiling of the housing 227 is provided at the same height as a ceiling of the housing 231. In addition, a bottom of the housing 227 is provided higher than a bottom of the housing 231.

The partition plates 232 are provided at positions corresponding to the substrates S and corresponding to the partition plates 226, respectively. It is preferable that the partition plate 226 and the partition plate 232 corresponding to the partition plate 226 are provided at the same height. In addition, when processing the substrate S, it is preferable that the substrate S, the partition plate 226 corresponding to the substrate S and the partition plate 232 corresponding to the partition plate 226 are provided at the same height. With such a structure, the gas flow in the horizontal direction passing over the substrate S and the partition plate 232 is formed by the gas supplied through each nozzle, as shown by each arrow in FIG. 1. By configuring the partition plate 232 as described above, it is possible to uniformize the pressure loss of the gas ejected (or discharged) through each of the substrates S. Therefore, the flow of the gas passing through each of the substrates S is formed in the horizontal direction toward the gas exhaust structure 213 while suppressing a gas flow in the vertical direction.

By providing the partition plates 226 and the partition plates 232, it is possible to uniformize the pressure loss in the vertical direction at both an upstream and a downstream of each of the substrates S. As a result, it is possible to reliably form a horizontal gas flow over the partition plate 226, the substrate S and the partition plate 232 while suppressing a vertical gas flow.

That is, the partition plates 226 are provided at locations corresponding to the substrates S, respectively, and spaces (which are defined (or partitioned) by the housing 227 and the partition plates 226) are respectively used as a plurality of gas supply holes through which the process gas is supplied toward upper surfaces of the substrates S. In addition, the partition plates 232 are provided at locations corresponding to the substrates S, respectively, and spaces (which are defined (or partitioned) by the housing 231 and the partition plates 232) are respectively used as a plurality of second exhaust holes configured to communicate between the process chamber 201 and a second exhaust pipe 281. By providing the gas supply holes and the second exhaust holes for the substrates S in a manner described above, it is possible to improve a uniformity of processing the plurality of substrates S (that is, a uniformity of a substrate processing between the plurality of substrates S).

The gas exhaust structure 213 is provided downstream of the downstream side gas guide 215. The gas exhaust structure 213 is constituted mainly by a housing 241 and an exhaust hole 244. The gas exhaust structure 213 is provided with a buffer structure serving as a space where the gases exhausted through the second exhaust holes between the partition plates 232 join together and are exhausted by a second exhauster (which is a second exhaust structure) 280 serving as an exhaust system. By uniformizing a flow rate of the gas exhausted through the second exhaust holes by using the buffer structure in a manner described above, it is possible to improve the uniformity of processing the plurality of substrates S. The exhaust hole 244 is provided at a downstream side of the housing 241 on a lower portion of the housing 241 in the horizontal direction. The second exhaust pipe 281 is connected to the process chamber 201 via the exhaust hole 244.

The gas exhaust structure 213 communicates with the space within the downstream side gas guide 215. The housing 231 and the housing 241 may form a structure with a continuous height. That is, a height of the ceiling of the housing 231 is configured to be the same as that of a ceiling of the housing 241, and a height of the bottom of the housing 231 is configured to be the same as that of a bottom of the housing 241.

The gas exhaust structure 213 is provided in a lateral direction of the reaction tube 210, and is a lateral exhaust structure configured to exhaust the gas along the lateral direction of the substrate S.

The process chamber 201 includes: a processing region A in which the substrate S is processed; and a heat insulating region B below the processing region A, in which a heat insulator (which serves as a heat insulating structure) 502 described later is disposed while the substrate support structure 300 is transferred (loaded) into the process chamber 201. The heat insulator 502 may also be referred to as a “heat insulating assembly”.

The housing 231 is configured such that a thermocouple 500 can be installed on a bottom surface of the housing 231. By providing the bottom of the housing 231 to be lower than the bottom of the housing 227 and providing the space within the downstream side gas guide 215 to be wider than a space within the upstream side gas guide 214, it is possible to prevent (or suppress) an inert gas supplied to the heat insulator 502 or an inner atmosphere (including the reaction by-products) of the heat insulating region B from entering (or flowing into) the processing region A, while ensuring a location (place) for installing the thermocouple 500. Therefore, the flow of the gas passing through each of the substrates S is formed in the horizontal direction toward the gas exhaust structure 213 while suppressing the gas flow in the vertical direction.

That is, the gas that has passed through the downstream side gas guide 215 is exhausted through the exhaust hole 244. When the gas is exhausted through the exhaust hole 244, since the gas exhaust structure 213 is not provided with a structure similar to the partition plate described above, the gas flow whose vertical component is non-zero is formed toward the exhaust hole 244.

The substrate support structure 300 includes a partition plate support 310 and a base structure 311, and is accommodated in the reaction tube 210. The substrates S are arranged directly below an inner wall of a top plate of the reaction tube 210. In addition, a process of moving the substrate S from the substrate support structure 300 by a vacuum transfer robot (not shown) in a transfer chamber 217 via a substrate loading/unloading port (not shown) can be performed and a process of loading the substrate S (which is moved from the substrate support structure 300) into the reaction tube 210 and forming a film on the surface of the substrate S can be performed. For example, the substrate loading/unloading port is provided on a side wall of the transfer chamber 217.

A plurality of partition plates including a partition plate 314 of a disk shape are fixed to the partition plate support 310 at a predetermined pitch therebetween. Hereafter, the plurality of partition plates including the partition plate 314 may also be simply referred to as “partition plates 314”. The substrates S are placed between the partition plates 314 at a predetermined interval therebetween. The partition plate 314 may be arranged directly below the substrate S. The partition plates 314 may be provided above and/or below the substrate S. The partition plates 314 are configured to separate spaces between adjacent substrates S from one another.

The substrates S are stacked and supported by the substrate support structure 300 at a predetermined interval therebetween in the vertical direction. The predetermined interval between the substrates S placed on the substrate support structure 300 is the same as a vertical interval (that is, the pitch described above) between the partition plates 314 fixed to the partition plate support 310. In addition, a diameter of the partition plate 314 is set to be larger than a diameter of the substrate S.

The substrate support structure 300 is configured to support a plurality of substrates (for example, 5 substrates) as the substrates S in a multistage manner in the vertical direction. By processing the plurality of substrates S simultaneously (at once) in a manner described above, it is possible to improve a productivity. Further, the present embodiment will be described by way of an example in which 5 substrates are supported by the substrate support structure 300 as the substrates S. However, the present embodiment is not limited thereto. For example, the substrate support structure 300 may be configured to support from 5 substrates to 50 substrates as the substrates S.

For example, in the present specification, a notation of a numerical range such as “5substrates to 50 substrates” means that a lower limit and an upper limit are contained in the numerical range. Therefore, for example, a numerical range “5 substrates to 50 substrates” means a range equal to or higher than 5 substrates and equal to or less than 50 substrates. The same also applies to other numerical ranges described in the present specification.

The heat insulator 502 is provided below the substrate support structure 300. An exhaust hole 503 serving as a first exhaust hole is provided at a wall surface (side surface) of the reaction tube 210 (that is, the process chamber 201) to be located at a lower portion of the process chamber 201 of the reaction tube 210 beside the heat insulator 502 and below an upper end of the heat insulator 502 when the substrate support structure 300 is loaded into the reaction tube 210. A first exhaust pipe 504 through which the inner atmosphere of the heat insulating region B is exhausted is connected to the exhaust hole 503.

The transfer chamber 217 is installed below the reaction tube 210 via the manifold 216. In the transfer chamber 217, the substrate S may be transferred to (and placed on) the substrate support structure (hereinafter, may also be simply referred to as a “boat”) 300 by the vacuum transfer robot via the substrate loading/unloading port, or the substrate S may be transferred (or taken) out of the substrate support structure 300 by the vacuum transfer robot.

Inside the transfer chamber 217, a vertical driving structure (also referred to as a “vertical driver”) 400 configured to drive the substrate support structure 300 and the partition plate support 310 in the vertical direction (up-down direction) can be accommodated (or stored). FIG. 1 shows a state in which the substrate support structure 300 is elevated by the vertical driving structure 400 and accommodated in the reaction tube 210. In addition, while the substrate support structure 300 is accommodated in the reaction tube 210, the heat insulator 502 is disposed at a lower portion of the reaction tube 210, and the heat insulator 502 occupies the heat insulating region B provided at the lower portion of the process chamber 201. Thereby, it is possible to reduce a heat conduction to the transfer chamber 217 from the process chamber 201.

For example, the vertical driving structure 400 includes: a rotational driving structure (also referred to as a “rotational driver”) 430 configured to rotate the substrate support structure 300 and the partition plate support 310 together; and a boat vertical driving structure (also referred to as a “boat vertical driver”) 420 configured to drive the substrate support structure 300 in the up-down direction relative to the partition plate support 310.

The rotational driving structure 430 and the boat vertical driving structure 420 are fixed to a base flange 401 serving as a lid supported by a side plate 403 on a base plate 402.

An annular space is provided between a support 441 and a support structure 440. A gas supply pipe 271 is connected to the annular space (which is provided between the support 441 and the support structure 440) below the heat insulator 502. The inert gas is supplied through the gas supply pipe 271 such that the inert gas is supplied to the heat insulator 502 from thereunder.

An O-ring 446 is installed on an upper surface of the base flange 401, and as shown in FIG. 1, by driving a vertical driving motor 410 such that the upper surface of the base flange 401 is elevated to a position where it is pressed against the transfer chamber 217, it is possible to maintain an inside (inner portion) of the reaction tube 210 airtight.

In addition, a hole 401a is provided at a center of the base flange 401 through which the support structure 440 passes, and an annular space is provided between the hole 401a and the support structure 440. A gas supply pipe 701 is connected to the annular space provided between the hole 401a and the support structure 440. The inert gas is supplied through the gas supply pipe 701 such that the inert gas is supplied from below the heat insulator 502 toward locations such as the upper surface of the base flange 401 and a periphery of the support structure 440.

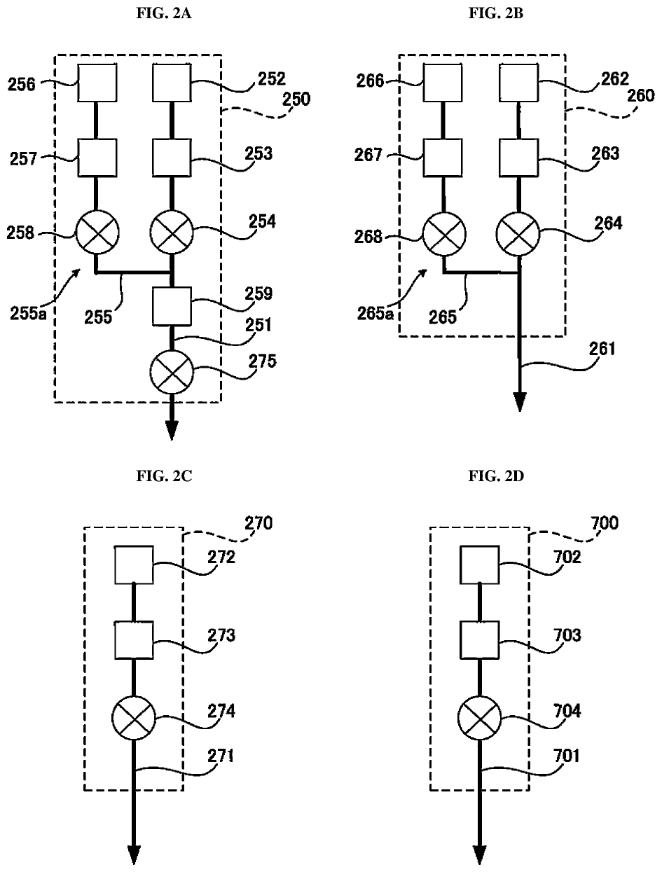

Subsequently, a gas supplier (which is a gas supply system) will be described in detail with reference to FIGS. 2A through 2D.

As shown in FIG. 2A, a first gas supply source 252, a mass flow controller (MFC) 253 serving as a flow rate controller (a flow rate control structure), a valve 254 serving as an opening/closing valve, a tank 259 serving as a storage configured to store a gas and a valve 275 are sequentially installed at the gas supply pipe 251 in this order from an upstream side to a downstream side of the gas supply pipe 251.

The first gas supply source 252 is a source of a first gas containing a first element (also referred to as a “first element-containing gas”). The first gas serves as a source gas, that is, one of process gases. Each of the process gases may also be referred to as the “process gas.”

A first gas supplier (which is a first gas supply system) 250 is constituted mainly by the gas supply pipe 251, the MFC 253, the valve 254, the tank 259 and the valve 275. The first gas supplier 250 may also be referred to as a “silicon-containing gas supplier” which is a silicon-containing gas supply system. The first gas supplier 250 may further include the first gas supply source 252.

A gas supply pipe 255 is connected to the gas supply pipe 251 at a downstream side of the valve 254 and an upstream side of the tank 259. An inert gas supply source 256, an MFC 257 and a valve 258 are sequentially installed at the gas supply pipe 255 in this order from an upstream side to a downstream side of the gas supply pipe 255. An inert gas (for example, nitrogen (N₂) gas) is supplied from the inert gas supply source 256.

An inert gas supplier (which is an inert gas supply system) 255a is constituted mainly by the gas supply pipe 255, the MFC 257 and the valve 258. The inert gas supplied from the inert gas supply source 256 acts as a purge gas for purging the gas stored (or remaining) in the reaction tube 210 when performing the substrate processing described later. The inert gas supplier 255a may further include the inert gas supply source 256. The first gas supplier 250 may further include the inert gas supplier 255a.

As shown in FIG. 2B, a second gas supply source 262, an MFC 263 and a valve 264 are sequentially installed at the gas supply pipe 261 in this order from an upstream side to a downstream side of the gas supply pipe 261.

The second gas supply source 262 is a source of a second gas containing a second element (also referred to as a “second element-containing gas”). The second gas serves as one of the process gases. Further, the second gas may serve as a reactive gas or a modification gas.

A second gas supplier (which is a second gas supply system) 260 is constituted mainly by the gas supply pipe 261, the MFC 263 and the valve 264. The second gas supplier 260 may further include the second gas supply source 262.

A gas supply pipe 265 is connected to the gas supply pipe 261 at a downstream side of the valve 264. An inert gas supply source 266, an MFC 267 and a valve 268 are sequentially installed at the gas supply pipe 265 in this order from an upstream side to a downstream side of the gas supply pipe 265. The inert gas (for example, the N₂ gas) is supplied from the inert gas supply source 266.

An inert gas supplier (which is an inert gas supply system) 265a is constituted mainly by the gas supply pipe 265, the MFC 267 and the valve 268. The inert gas supplied from the inert gas supply source 266 acts as the purge gas for purging the gas stored (or remaining) in the reaction tube 210 when performing the substrate processing described later. The inert gas supplier 265a may further include the inert gas supply source 266. The second gas supplier 260 may further include the inert gas supplier 265a.

As shown in FIG. 2C, an inert gas supply source 272, an MFC 273 and a valve 274 are sequentially installed at the gas supply pipe 271 in this order from an upstream side to a downstream side of the gas supply pipe 271. The inert gas (for example, the N₂ gas) is supplied from the inert gas supply source 272.

An inert gas supplier (which is an inert gas supply system) 270 serving as a first inert gas supplier (which is a first inert gas supply system) is constituted mainly by the gas supply pipe 271, the MFC 273 and the valve 274. The inert gas supplier 270 may further include the inert gas supply source 272. The inert gas supplier 270 is configured to supply the inert gas toward a subsidiary heater serving as a heating structure in the heat insulator 502. The inert gas supplied from the inert gas supply source 272 acts as the purge gas capable of purging an inside (inner portion) and a periphery of the heat insulator 502 which constitutes the heat insulating region B disposed at the lower portion of the process chamber 201 when the substrate support structure 300 is loaded into the process chamber 201.

As shown in FIG. 2D, an inert gas supply source 702, an MFC 703 and a valve 704 are sequentially installed at the gas supply pipe 701 in this order from an upstream side to a downstream side of the gas supply pipe 701. The inert gas (for example, the N₂ gas) is supplied from the inert gas supply source 702.

An inert gas supplier (which is an inert gas supply system) 700 serving as a second inert gas supplier (which is a second inert gas supply system) is constituted mainly by the gas supply pipe 701, the MFC 703 and the valve 704. The inert gas supplier 700 may further include the inert gas supply source 702. The inert gas supplier 700 is configured to supply the inert gas from below the heat insulator 502 toward the process chamber 201. The inert gas supplied from the inert gas supply source 702 acts as the purge gas capable of purging locations such as a lower portion of the heat insulator 502 (which constitutes the heat insulating region B disposed at the lower portion of the process chamber 201), the upper surface of the base flange 401 and the periphery of the support structure 440 in a state where the substrate support structure 300 is loaded in the process chamber 201.

Subsequently, an exhauster (which is an exhaust system) will be described.

A vacuum pump 284 serving as a vacuum exhaust apparatus is connected to the second exhaust pipe 281 via a valve 282 and an APC (Automatic Pressure Controller) valve 283 serving as a pressure regulator (which is a pressure adjusting structure). Thereby, the reaction tube 210 can be vacuum-exhausted such that a pressure (inner pressure) of the reaction tube 210 reaches and is maintained at a predetermined pressure (vacuum degree).

The second exhauster (which is a second exhaust system) 280 is constituted by the second exhaust pipe 281, the valve 282 and the APC valve 283. The second exhauster 280 serves as a part of the exhauster through which the gas in the process chamber 201 is exhausted. Further, the second exhauster 280 may further include the vacuum pump 284. That is, the second exhauster 280 includes the second exhaust pipe 281 communicating with the process chamber 201 of the reaction tube 210, and is configured to exhaust an atmosphere (inner atmosphere) of the process chamber 201 through the second exhaust pipe 281. The second exhauster 280 is configured to be capable of exhausting the process gas along a direction away from the side of the reaction tube 210 from which the process gas is supplied.

A first exhauster (which is a first exhaust system) 508 is constituted by the first exhaust pipe 504 and a valve 506. A downstream end of the first exhaust pipe 504 is connected to the second exhaust pipe 281 at a confluence portion provided at an upstream side of the valve 282 of the second exhaust pipe 281.

That is, the first exhaust pipe 504 is connected to a side portion of the heat insulator 502 between the inert gas supplier 270 and the process chamber 201 in the vertical direction when the substrate support structure 300 is loaded into the process chamber 201. Thereby, the inert gas supplied to the heat insulator 502 from thereunder can flow through the heat insulating region B in the process chamber 201 and can be exhausted through the side portion of the heat insulator 502. That is, the first exhauster 508 includes the first exhaust pipe 504 communicating with the heat insulating region B of the reaction tube 210, and is configured to exhaust the inert gas supplied to the heat insulating region B and the inner atmosphere of the heat insulating region B.

That is, the process gas supplied to the processing region A is exhausted separately via the second exhaust pipe 281, and the inert gas supplied to the heat insulating region B is exhausted separately via the first exhaust pipe 504. Thus, while suppressing an adhesion of the reaction by-products by purging the heat insulating region B with the inert gas, it is possible to suppress an effect of the inert gas on the processing region A. In other words, it is possible to prevent a decrease in a processing efficiency due to a dilution of the process gas by the inert gas, and it is also possible to improve the uniformity of processing the plurality of substrates S.

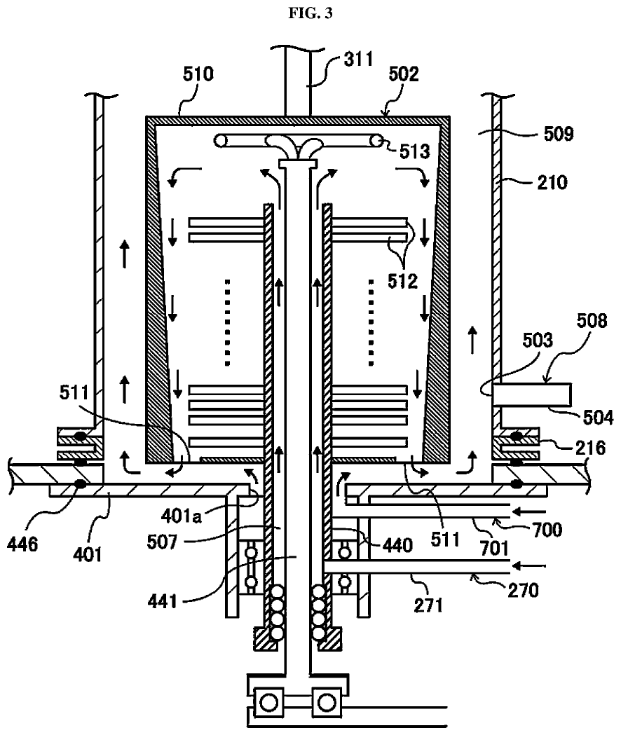

Subsequently, the heat insulator 502 and the periphery thereof will be described in detail with reference to FIG. 3.

The heat insulator 502 is disposed below the substrate support structure 300. For example, the heat insulator 502 includes: a vessel 510; a subsidiary heater 513 disposed at an upper portion inside the vessel 510; and a plurality of heat insulating plates 512 serving as a heat insulating component disposed below the subsidiary heater 513. Thereby, it is possible to suppress a decrease in a temperature of the substrate S located at the lower portion of the process chamber 201, and it is also possible to heat the substrate S from thereunder. Hereinafter, each of the heat insulating plates 512 may also be referred to as a “heat insulating plate 512”. In addition, the subsidiary heater 513 can heat a center portion of the substrate S, whose temperature is more likely to decrease than that of an edge of the substrate S. Thereby, it is possible to improve the uniformity of processing of the plurality of substrates S and it is also possible to improve a uniformity of processing the substrate S on the surface thereof (that is, a uniformity of the substrate processing on the surface of the substrate S). The subsidiary heater 513 is supported by the support 441. The heat insulating plates 512 are stacked in and vertically supported in a horizontal orientation substantially parallel to the support structure 440. That is, in the vessel 510, the subsidiary heater 513 supported by the support 441 and the heat insulating plates 512 (which are stacked in and vertically supported in the horizontal orientation substantially parallel to the support structure 440) are accommodated.

The vessel 510 is configured as a hollow structure whose outer wall surface (that is, an outer surface) is of a cylindrical shape and whose inner wall surface (that is, an inner surface) is of an inverted truncated cone shape. That is, an outer diameter of the vessel 510 is constant, and an inner diameter of the vessel 510 is set to decrease from an upper surface to a lower surface of the vessel 510. In other words, an inner side surface of the vessel 510 is configured such that a horizontal cross-sectional area of an inner space of the vessel 510 increases continuously along an upward direction.

The support 441 and the support structure 440 penetrate a center of a bottom surface of the vessel 510 in a concentric manner. In addition, an opening 511 through which an inside and an outside of the vessel 510 can communicate with each other is provided in the bottom surface of the vessel 510.

In addition, a distance between the inner side surface of the vessel 510 and an edge of one of the heat insulating plates 512 located at a specific height is set to be shorter than a distance between the inner side surface of the vessel 510 and an edge of another of the heat insulating plates 512 located at a height above the specific height. Thereby, since a width of a flow passage for the inert gas is narrowed at a lower portion of the vessel 510, it is possible for the inert gas to stagnate (or remain) in the upper portion of the vessel 510.

For example, the heat insulating plate 512 is made of a heat resistant material such as quartz and SiC. Thereby, the heat is less likely to be transmitted from the process chamber 201 to the transfer chamber 217. For example, the heat insulating component is not limited to the heat insulating plates 512. For example, a heat insulating cylinder made of a heat resistant material such as quartz and SiC may be provided as the heat insulating component.

The annular space between the support 441 and the support structure 440 is used as an inert gas flow passage 507 through which the inert gas flows. The gas supply pipe 271 is connected to the inert gas flow passage 507 such that the inert gas supplied through the gas supply pipe 271 is supplied toward the subsidiary heater 513 inside the vessel 510 through the inert gas flow passage 507. Thereby, it is possible to suppress an adhesion of the process gas or the adhesion of the reaction by-products to the subsidiary heater 513. The inert gas supplied toward the subsidiary heater 513 inside the vessel 510 flows downward in the vessel 510 and is exhausted by the first exhauster 508 via the opening 511 through the upper surface of the base flange 401, an inert gas flow passage 509 (which is a space between the outer side surface of the vessel 510 and the reaction tube 210) and the exhaust hole 503. As described above, the inner diameter of the vessel 510 is set to decrease from the upper surface to the lower surface of the vessel 510. Therefore, the inert gas tends to remain in the upper portion of the vessel 510. In other words, the process gas supplied to the processing region A is less likely to flow into the vessel 510. In addition, a volume of the vessel 510 is smaller than that of another vessel such as a hollow cylindrical vessel whose inner diameter is substantially the same as that of the upper surface of the vessel 510. In other words, a smaller flow rate of the inert gas can be used for purging. Thus, by using the heat insulator 502, it is possible to reduce a flow rate of the purge gas (inert gas) for purging the inside of the heat insulator 502.

In addition, as described above, the gas supply pipe 701 is connected to the annular space between the hole 401a and the support structure 440. The inert gas supplied through the gas supply pipe 701 below the heat insulator 502 is exhausted by the first exhauster 508 via the periphery of the support structure 440 in the process chamber 201, the upper surface of the base flange 401, the inert gas flow passage 509 and the exhaust hole 503. Thereby, it is possible to suppress the adhesion of the reaction by-products on locations such as the periphery of the support structure 440 and a portion below the heat insulator 502.

That is, the inert gas supplied through the gas supply pipes 271 and 701 purges the inside of the heat insulator 502 and the heat insulating region B, and is exhausted through the first exhauster 508.

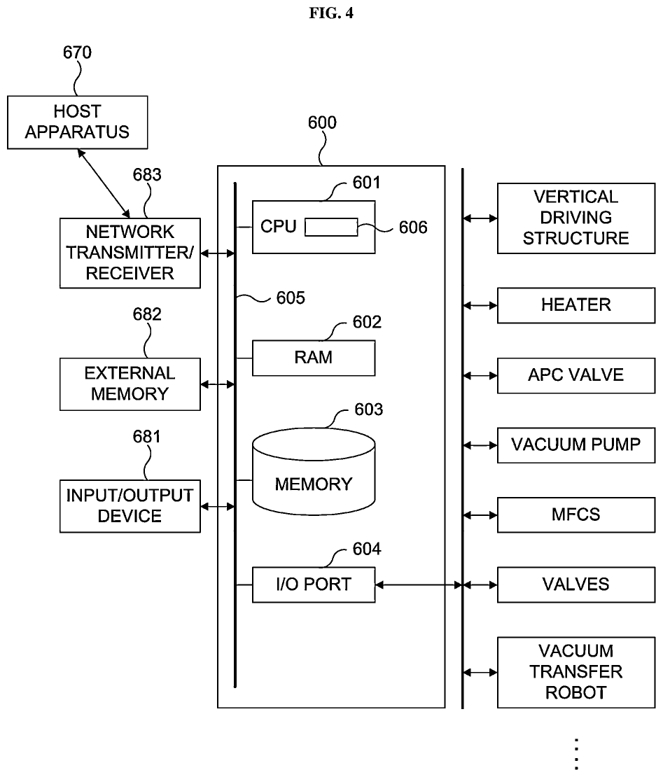

Subsequently, a controller 600 serving as a control structure (control apparatus) will be described with reference to FIG. 4. The substrate processing apparatus 10 includes the controller 600 configured to control operations of components constituting the substrate processing apparatus 10.

FIG. 4 is a diagram schematically illustrating a configuration of the controller 600. For example, the controller 600 is constituted by a computer including a CPU (Central Processing Unit) 601, a RAM (Random Access Memory) 602, a memory 603 serving as a memory structure and an I/O port (input/output port) 604. The RAM 602, the memory 603 and the I/O port 604 can exchange data with the CPU 601 via an internal bus 605. The transmission/reception of the data in the substrate processing apparatus 10 may be performed by an instruction from a transmission/reception instruction controller 606 which is one of functions of the CPU 601.

A network transmitter/receiver 683 connected to a host apparatus 670 via a network is provided at the controller 600. For example, the network transmitter/receiver 683 is capable of receiving data such as information regarding a processing history and a processing schedule for the substrate S stored in a pod from the host apparatus 670.

For example, the memory 603 may be embodied by a component such as a flash memory and an HDD (Hard Disk Drive). The memory 603 stores process conditions for each type of substrate processing. That is, a control program for controlling the operations of the substrate processing apparatus 10 or a process recipe in which information such as procedures and conditions of the substrate processing is stored may be readably stored in the memory 603.

The process recipe is obtained by combining steps of the substrate processing described later, and acts as a program that is executed by the controller 600 to obtain a predetermined result by performing the steps of the substrate processing described later. Hereinafter, the process recipe and the control program may be collectively or individually referred to simply as a “program.” Thus, in the present specification, the term “program” may refer to the process recipe alone, may refer to the control program alone, or may refer to both of the process recipe and the control program. The RAM 602 serves as a memory area (work area) in which the program or the data read by the CPU 601 is temporarily stored.

The I/O port 604 is electrically connected to the components of the substrate processing apparatus 10, which are mentioned above.

The CPU 601 is configured to read and execute the control program from the memory 603, and is further configured to read the process recipe from the memory 603 in accordance with an instruction such as an operation command inputted from an input/output device 681. The CPU 601 is further configured to be capable of controlling the substrate processing apparatus 10 in accordance with contents of the read process recipe. The CPU 601 is further configured to be capable of setting an amount (supply amount) of the inert gas supplied through each of the inert gas suppliers 270 and 700 in accordance with each type of substrate processing. The CPU 601 is further configured to be capable of individually controlling the first exhauster 508 communicating with the heat insulating region B and the second exhauster 280 communicating with the processing region A in accordance with the type and the conditions of the substrate processing.

The CPU 601 includes the transmission/reception instruction controller 606. For example, the controller 600 according to the present embodiment may be embodied by preparing an external memory 682 (for example, a magnetic disk such as a hard disk, an optical disk such as a DVD, a magneto-optical disk such as an MO, a semiconductor memory such as a USB memory) storing the program described above and by installing the program onto the computer by using the external memory 682. Further, a method of providing the program to the computer is not limited to such a method using the external memory 682. For example, the program may be directly provided to the computer by a communication interface such as the Internet and a dedicated line instead of the external memory 682. Further, the memory 603 and the external memory 682 may be embodied by a non-transitory computer-readable recording medium. Hereinafter, the memory 603 and the external memory 682 may be collectively or individually referred to as a “recording medium”. Thus, in the present specification, the term “recording medium” may refer to the memory 603 alone, may refer to the external memory 682 alone, or may refer to both of the memory 603 and the external memory 682.

### (2) Substrate Processing (Substrate Processing Method)

Hereinafter, as a part of a manufacturing process of a semiconductor device (that is, a method of manufacturing the semiconductor device), the substrate processing will be described by way of an example in which a step (film forming process) of forming a film on the substrate S is performed by using the substrate processing apparatus 10 described above. Further, in the following description, the controller 600 controls the operations of the components constituting the substrate processing apparatus 10.

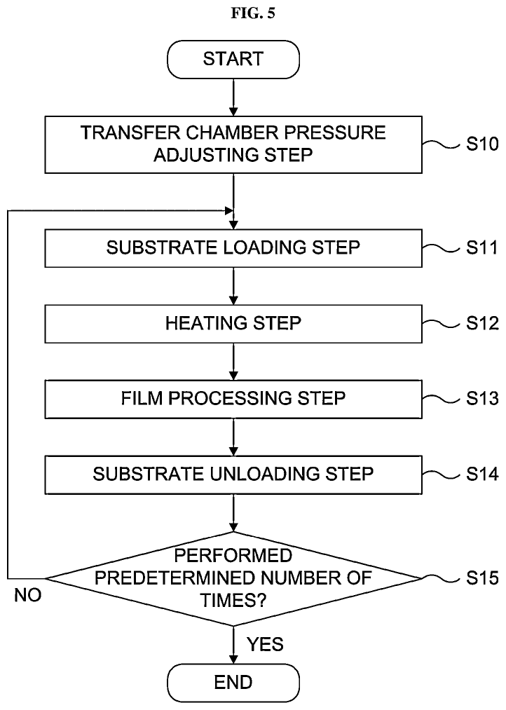

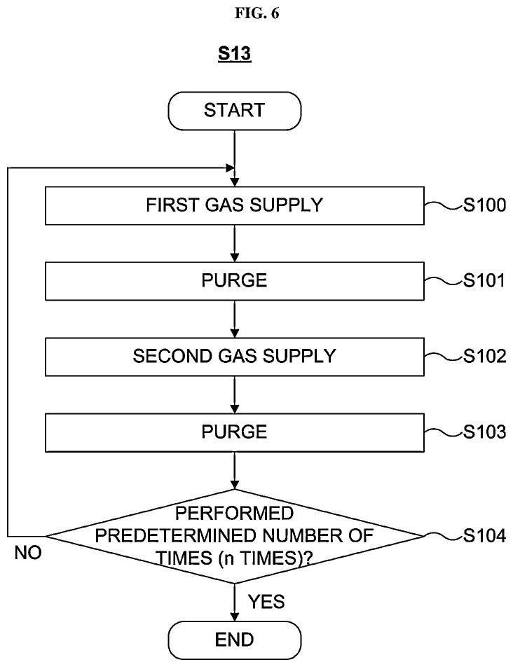

Hereinafter, the film forming process will be described with reference to FIGS. 5 and 6 by way of an example in which the film is formed on the substrate S by using the first gas and the second gas as the process gases and by alternately supplying the first gas and the second gas.

In the present specification, the term “substrate” may refer to “a substrate itself,” or may refer to “a substrate and a stacked structure (aggregated structure) of a predetermined layer (or layers) or a film (or films) formed on a surface of the substrate.” In the present specification, the term “a surface of a substrate” may refer to “a surface of a substrate itself,” or may refer to “a surface of a predetermined layer (or a predetermined film) formed on a substrate.” Thus, in the present specification, “forming a predetermined layer (or a film) on a substrate” may refer to “forming a predetermined layer (or a film) directly on a surface of a substrate itself,” or may refer to “forming a predetermined layer (or a film) on a surface of another layer (or another film) formed on a substrate.” In the present specification, the terms “substrate” and “wafer” may be used as substantially the same meaning.

### <S10>

A transfer chamber pressure adjusting step S10 will be described. In the present step, a pressure (inner pressure) of the transfer chamber 217 is set to the same level as that of a vacuum transfer chamber (not shown) provided adjacent to the transfer chamber 217.

### <S11>

Subsequently, a substrate loading step S11 will be described. When an atmosphere (inner atmosphere) of the transfer chamber 217 reaches and is maintained at a vacuum level, a transfer of the substrate S is started. When the substrate S reaches the vacuum transfer chamber, a gate valve is opened. Then, the substrate S is loaded (transferred) into the transfer chamber 217 by the vacuum transfer robot.

In the present step, the substrate support structure 300 stands by in the transfer chamber 217, and the substrate S is transferred to the substrate support structure 300. When a predetermined number of the substrates S are transferred to the substrate support structure 300, the vacuum transfer robot is retracted, and the substrate support structure 300 is elevated by the vertical driving structure 400 to move the substrates S into the process chamber 201 in the reaction tube 210. The substrates S are moved into the process chamber 201 while stacked in the vertical direction.

When moving the substrate S into the reaction tube 210, the surface of the substrate S is positioned so as to be aligned at the same height as the partition plate 226 and the partition plate 232 corresponding thereto.

### <S12>

Subsequently, a heating step S12 will be described. When the substrate S is loaded into the process chamber 201 in the reaction tube 210, the inner pressure of the reaction tube 210 is controlled (adjusted) to a predetermined pressure, and a surface temperature of the substrate S is adjusted to a predetermined temperature by controlling the heater 211 and the subsidiary heater 513.

### <S13>

Subsequently, a film processing step S13 will be described. The film processing step S13 is performed by performing the following steps S100 to S104 to the substrate S in accordance with the process recipe while the substrates S are stacked on the substrate support structure 300 and accommodated in the process chamber 201.

### <First Gas Supply, Step S100>

First, the first gas is supplied into the reaction tube 210 in a flash-like manner (that is, a large amount of the first gas is temporarily supplied into the reaction tube 210). Specifically, the valve 275 is opened so as to supply the first gas into the gas supply pipe 251 from the tank 259 in which the first gas is stored in advance. After a predetermined time has elapsed, the valve 275 is closed to stop a supply of the first gas into the gas supply pipe 251. The first gas is supplied in a large amount at once into the reaction tube 210 from the gas supply structure 212 via the distributor 125, the nozzle 223 and the upstream side gas guide 214. Then, the first gas is exhausted through a space above the substrate S, the downstream side gas guide 215, the gas exhaust structure 213 and the second exhaust pipe 281. In the present step, while the first gas is being supplied into the process chamber 201, the valve 254 may be opened or closed. Further, when the first gas is being supplied, the valve 258 may be opened so as to supply the inert gas such as the N₂ gas into the gas supply pipe 251 via the gas supply pipe 255. Further, when the first gas is being supplied, in order to prevent the first gas from entering the gas supply pipe 261, the valve 268 may be opened so as to supply the inert gas into the gas supply pipe 261.

In the present step, for example, the APC valve 283 is appropriately adjusted such that the inner pressure of the reaction tube 210 is within a range from 1 Pa to 3,990 Pa. In the following, for example, a temperature of the heater 211 is adjusted such that a temperature of the substrate S reaches and is maintained at a temperature within a range from 100° C. to 1,500° C., preferably from 400° C. to 800° C.

In the present step, the first gas is supplied in a large amount at once from beside the substrate S to the substrate S in the horizontal direction through the gas supply structure 212 (which is in communication with the inner portion of the reaction tube 210), and is exhausted through the second exhaust pipe 281.

In addition, in the present step, the valve 274 is opened, and the valve 506 is controlled not to be fully closed, preferably to be fully opened. The inert gas whose flow rate is adjusted by the MFC 273 is supplied toward the subsidiary heater 513 inside the vessel 510 through the gas supply pipe 271 and the inert gas flow passage 507. Then, the inert gas flows out of the vessel 510 through the opening 511 (which is provided at the bottom surface of the vessel 510), flows over the upper surface of the base flange 401 and into the inert gas flow passage 509, and then is exhausted through the first exhaust pipe 504 via the exhaust hole 503.

In addition, in the present step, the valve 704 is opened. The inert gas whose flow rate is adjusted by the MFC 703 is supplied through the gas supply pipe 701 toward the periphery of the support structure 440 below the heat insulator 502 in the process chamber 201. Then, the inert gas flows through a space between the lower surface of the vessel 510 and the upper surface of the base flange 401 and the inert gas flow passage 509, and is exhausted through the first exhaust pipe 504 via the exhaust hole 503.

By supplying the first gas in the flash-like manner, a pressure in the upper portion of the process chamber 201 is instantaneously increased. Therefore, the amount (supply amount) of the inert gas supplied through the inert gas suppliers 270 and 700 to the heat insulator 502 is set to be greater than that of the inert gas supplied during a purge (for example, a purge S101) described later.

That is, in a state where the substrate S loaded into the process chamber 201 is heated, while the first gas is supplied to the processing region A for the substrate S, the valve 282 is opened to exhaust the gas in the process chamber 201 through the second exhaust pipe 281. Further, in the present step, while the inert gas is supplied through the inert gas suppliers 270 and 700 to the heat insulating region B below the processing region A, the valve 506 is opened to exhaust the gas through the first exhaust pipe 504.

As the first gas, for example, a silicon (Si)-containing gas serving as the source gas may be used. As the silicon-containing gas, for example, a gas containing silicon and chlorine (Cl) (such as hexachlorodisilane (Si₂Cl₆, abbreviated as HCDS) gas) may be used.

### <Purge, Step S101>

In the present step, the valve 254 is closed to stop the supply of the first gas, and the valves 258, 275, 268, 274 and 704 are opened to supply the inert gas serving as the purge gas into the gas supply pipes 255, 265, 271 and 701. When supplying the inert gas, with the valve 282 of the second exhaust pipe 281, the APC valve 283 and the valve 506 of the first exhaust pipe 504 open, the vacuum pump 284 vacuum-exhausts an atmosphere (inner atmosphere) of the reaction tube 210.

### <Second Gas Supply, Step S102>

After a predetermined time has elapsed from a start of the purge (that is, the purge S101), the valve 268 is closed and the valve 264 is opened to supply the second gas into the gas supply pipe 261. The second gas whose flow rate is adjusted by the MFC 263 is supplied into the reaction tube 210 from the gas supply structure 212 via the distributor 125, the nozzle 224 and the upstream side gas guide 214. Then, the second gas is exhausted through the space above the substrate S, the downstream side gas guide 215, the gas exhaust structure 213 and the second exhaust pipe 281. Further, when the second gas is being supplied, in order to prevent the second gas from entering the gas supply pipe 251, the valves 258 and 275 are opened so as to supply the inert gas through the nozzle 223.

In the present step, the second gas is supplied from beside the substrate S to the substrate S in the horizontal direction through the gas supply structure 212 (which is in communication with the inner portion of the reaction tube 210), and is exhausted through the second exhaust pipe 281.

In addition, in the present step, the valve 274 is opened, and the valve 506 is controlled not to be fully closed, preferably to be fully opened. The inert gas whose flow rate is adjusted by the MFC 273 is supplied toward the subsidiary heater 513 inside the vessel 510 through the gas supply pipe 271 and the inert gas flow passage 507. Then, the inert gas supplied toward the subsidiary heater 513 flows out of the vessel 510 through the opening 511 (which is provided at the bottom surface of the vessel 510), flows over the upper surface of the base flange 401 and into the inert gas flow passage 509, and then is exhausted through the first exhaust pipe 504 via the exhaust hole 503.

In addition, in the present step, the valve 704 is opened. The inert gas whose flow rate is adjusted by the MFC 703 is supplied through the gas supply pipe 701 toward the periphery of the support structure 440 below the heat insulator 502 in the process chamber 201. Then, the inert gas flows through the space between the lower surface of the vessel 510 and the upper surface of the base flange 401 and the inert gas flow passage 509, and is exhausted through the first exhaust pipe 504 via the exhaust hole 503.

That is, in the state where the substrate S loaded into the process chamber 201 is heated, while the second gas is supplied to the processing region A for the substrate S, the valve 282 is opened to exhaust the gas in the process chamber 201 through the second exhaust pipe 281. Further, in the present step, while the inert gas is supplied through the inert gas suppliers 270 and 700 to the heat insulating region B below the processing region A, the valve 506 is opened to exhaust the gas through the first exhaust pipe 504.

As the second gas, for example, a gas serving as the reactive gas reacting with the first gas may be used. As the reactive gas, for example, a gas containing hydrogen (H) and nitrogen (N) may be used. As the gas containing hydrogen and nitrogen, for example, a gas such as ammonia (NH₃), diazene (N₂H₂) gas, hydrazine (N₂H₄) gas and N₃H₈ gas may be used.

### <Purge, Step S103>

After a predetermined time has elapsed from a supply of the second gas, the valve 264 is closed to stop the supply of the second gas. In addition, the valves 258, 275, 268, 274 and 704 are opened to supply the inert gas serving as the purge gas into the gas supply pipes 255, 265, 271 and 701. When supplying the inert gas, with the valve 282 of the second exhaust pipe 281, the APC valve 283 and the valve 506 of the first exhaust pipe 504 open, the vacuum pump 284 vacuum-exhausts the inner atmosphere of the reaction tube 210. Thereby, it is possible to suppress a reaction between the first gas and the second gas in gaseous states in the reaction tube 210.

### <Performing Predetermined Number of Times, Step S104>

A cycle (in which the steps S100 to S103 described above are sequentially and non-simultaneously performed in this order) is performed a predetermined number of times (n times, where n is an integer of 1 or more). As a result, it is possible to form a film of a predetermined thickness on the substrate S. In the present embodiment, for example, a silicon nitride (SiN) film is formed.

In the step S100 or the step S102, the first gas or the second gas supplied to the process chamber 201 forms a gas flow in the upstream side gas guide 214, the space above the substrate S, and the downstream side gas guide 215. When forming the gas flow, the first gas or the second gas is supplied to the substrate S without a pressure loss above each of the substrates S. Thereby, it is possible to uniformly perform the substrate processing between the substrates S. By respectively supplying the first gas and the second gas from the gas supply structure 212 to the gas exhaust structure 213, it is possible to form a horizontal gas flow in the process chamber 201. Thereby, it is possible to suppress the effect of the inert gas supplied to the heat insulating region B.

In addition, in the state where the substrate S loaded into the process chamber 201 is heated, the first gas, the second gas and the reaction by-products are exhausted through the second exhaust pipe 281 connected to the process chamber 201 while alternately supplying the first gas and the second gas to the process chamber 201. When exhausting the first gas, the second gas and the reaction by-products, the inert gas is exhausted through the first exhaust pipe 504 connected to the exhaust hole 503 beside the heat insulator 502 while supplying the inert gas into the heat insulator 502 (which constitutes the heat insulating region B disposed at the lower portion of the process chamber 201) from thereunder. That is, the inert gas passed through locations such as the inside of the heat insulator 502 and the periphery of the support structure 440 is exhausted via the first exhaust pipe 504 before flowing upward beyond the heat insulator 502. Therefore, the inert gas supplied to the heat insulating region B is less likely to flow into the processing region A.

In other words, it is possible to prevent the lowermost substrate (among the substrates S supported by the substrate support structure 300) from affecting a horizontal gas flow. Thus, it is possible to make the gas flow similar between the upper portion and the lower portion of the process chamber 201. As a result, it is possible to uniformly process the plurality of substrates S stacked in the vertical direction, and it is also possible to improve the uniformity of processing the plurality of substrates S.

In addition, it is possible to prevent (or suppress) the first gas, the second gas and the reaction by-products from flowing into the heat insulator 502 and depositing the film inside the vessel 510 or a periphery of the vessel 510. By exhausting the inner atmosphere of the heat insulating region B through the first exhaust pipe 504 (which is different from an exhaust pipe through which an atmosphere (inner atmosphere) of the processing region A is exhausted), it is possible to prevent the reaction by-products from adhering to components arranged in the heat insulating region B, such as the subsidiary heater 513 and the support structure 440 and from adhering to a periphery of the valve 506. In addition, it is possible to prevent the reaction by-products (also referred to as the “particles”) from entering the processing region A.

### <S14>

Subsequently, a substrate unloading step S14 will be described. In the substrate unloading step S14, the substrate S processed as described above is transferred (unloaded) out of the transfer chamber 217 in the order reverse to that of the substrate loading step S11.

### <S15>

Subsequently, a determination step S15 will be described. In the present step, it is determined whether or not the processing of the substrate S described above (that is, the steps S11 to S14) has been performed a predetermined number of times. When it is determined that the processing has not been performed the predetermined number of times, the substrate loading step S11 is performed again to process a subsequent substrate S to be processed. When it is determined that the processing has been performed the predetermined number of times, the substrate processing is terminated.

While the present embodiment is described by way of an example in which the horizontal gas flow is formed, it is sufficient as long as a main flow of the gas is generally formed in the horizontal direction. Further, a gas flow may be diffused in the vertical direction as long as it does not affect a uniform processing of the plurality of substrates S.

Further, in the above, various expressions such as “the same,” “similar” and the like are used. However, it goes without saying that the expressions described above may mean “substantially the same.”

### (3) Other Embodiments of Present Disclosure

While the technique of the present disclosure is described in detail by way of the embodiment mentioned above, the technique of the present disclosure is not limited thereto and may be modified in various ways without departing from the scope thereof. For example, the technique of the present disclosure may be modified as shown below. In the substrate processing apparatus according to embodiments described below, substantially the same components as those of the first embodiment described with reference to FIG. 1 will be denoted by like reference numerals, and detailed descriptions thereof will be omitted. That is, only components different from those of the first embodiment mentioned above will be described in detail.

### <Second Embodiment>

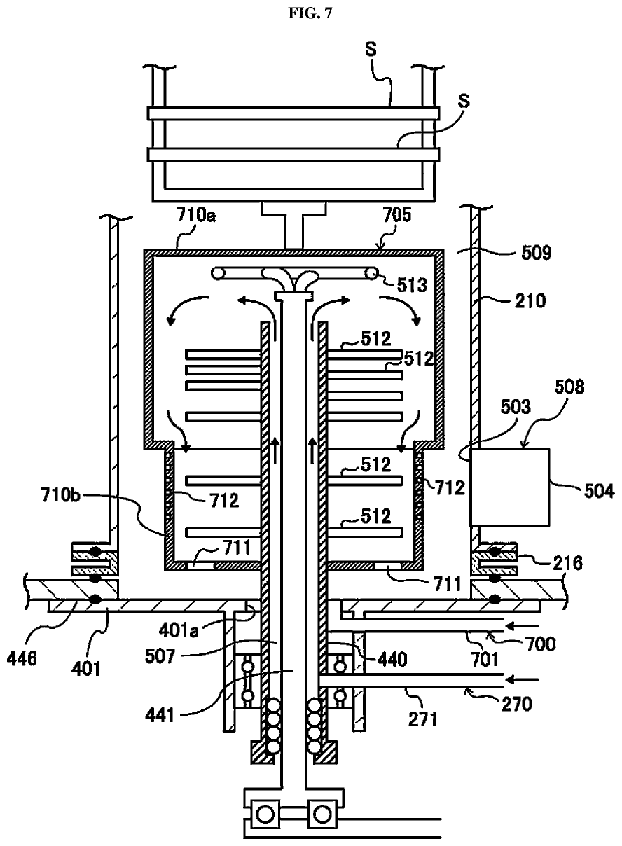

FIG. 7 is a diagram schematically illustrating a heat insulator 705 and a periphery thereof according to a second embodiment of the present disclosure. A shape of the heat insulator 705 according to the second embodiment is different from that of the heat insulator 502 described above.

For example, the heat insulator 705 includes: a vessel 710a of a hollow cylindrical shape; and a vessel 710b of a hollow cylindrical shape arranged below the vessel 710a. The vessel 710a and the vessel 710b are arranged in a manner concentric to each other and are capable of communicating with each other. In addition, an opening 711 is provided in a bottom surface of the vessel 710b. An outer diameter of the vessel 710b is set to be smaller than that of the vessel 710a, and an inner diameter of the vessel 710b is set to be smaller than that of the vessel 710a. In other words, the heat insulator 705 is configured such that a volume and a cross-sectional area of the vessel 710b arranged below the vessel 710a are smaller than those of the vessel 710a arranged above the vessel 710b, and such that a horizontal cross-sectional area of an inner space of the heat insulator 705 decreases stepwise along a downward direction. In addition, a stepped structure (stepped portion) is provided on an inner side surface and an outer side surface of the heat insulator 705. Thereby, it is possible for the inert gas to easily stagnate (or remain) in the vessel 710a in which the subsidiary heater 513 is disposed. Further, the process gas supplied to the processing region A is less likely to flow into the vessel 710a. Thus, by using the heat insulator 705, it is possible to reduce the flow rate of the inert gas (purge gas) for purging an inside (inner portion) of the heat insulator 705.

In addition, a gap (that is, a distance) between the inner side surface of the vessel 710b and the edge of its corresponding heat insulating plate 512 is set to be narrower (that is, smaller) than a gap (that is, a distance) between the inner side surface of the vessel 710a and an edge of its corresponding heat insulating plate 512). In other words, by narrowing a flow passage at the lower portion of the heat insulator 705, it is possible for the inert gas to easily stagnate (remain) in the upper portion of the heat insulator 705. Further, the process gas supplied to the processing region A is less likely to flow into the vessel 710a and the vessel 710b. In other words, it is possible to reduce the flow rate of the purge gas (inert gas) for purging the inside of the heat insulator 705.

In addition, a gap (distance) between an outer side surface of the vessel 710b and an inner side surface of the reaction tube 210 is set to be wider than a gap (distance) between an outer side surface of the vessel 710a and the inner side surface of the reaction tube 210. Further, for example, a plurality of grooves 712 serving as concave portions are provided substantially horizontally on the outer side surface of the vessel 710b such that a height of each of the grooves 712 falls within a height range of the exhaust hole 503. That is, it can be said that the heat insulator 705 includes a structure configured to promote a horizontal gas flow in a region (a space or a height range) located at an outer periphery of the heat insulator 705 at a height same as or lower than that of the first exhaust hole. Thereby, the inert gas supplied into the heat insulator 705 or the periphery of the support structure 440 can easily flow substantially in the horizontal direction in a space between the outer side surface of the vessel 710b and the inner side surface of the reaction tube 210. In addition, the exhaust hole 503 is provided at the wall surface of the reaction tube 210 beside the stepped structure (which is a connection structure connecting the vessel 710a and the vessel 710b and provided below the upper end of the heat insulator 705) of the vessel 710b to face the plurality of grooves 712. Thereby, it is possible to easily exhaust the inert gas (which is supplied into the heat insulator 705 or the periphery of the support structure 440) from the process chamber 201. For example, the plurality of grooves 712 may range from the upper portion to the lower portion of the outer side surface of the vessel 710b, or to a bottom end of the vessel 710b.

That is, the exhaust hole 503 is provided at the wall surface of the reaction tube 210 beside the stepped structure (which is the connection structure connecting the vessel 710a and the vessel 710a and provided below the upper end of the heat insulator 705) of the vessel 710b to face the plurality of grooves 712. In addition, a space (also referred to as a “first space”) is provided at an outer periphery of the vessel 710b within a height range including that of the exhaust hole 503. The first space is wider than a space (also referred to as a “second space”) thereabove. That is, the inert gas supplied to the heat insulating region B from below the heat insulator 705 can easily flow in the horizontal direction, a conductance of the first space is greater than that of the second space above the exhaust hole 503, and the pressure loss can be reduced in the first space compared to the second space. In addition, a space (also referred to as a “third space”) is provided at a lowermost portion (bottom) of the vessel 710b. The third space is wider than the second space above the exhaust hole 503 such that the inert gas supplied to the heat insulating region B is more likely to flow in the horizontal direction from beside the vessel 710b without flowing into the processing region A. That is, the inert gas supplied into the heat insulator 705 or the periphery of the support structure 440 is exhausted via the first exhaust pipe 504 before flowing upward beyond the vessel 710b. As a result, the inert gas supplied to the heat insulating region B is less likely to flow into the processing region A.

### <Third Embodiment>

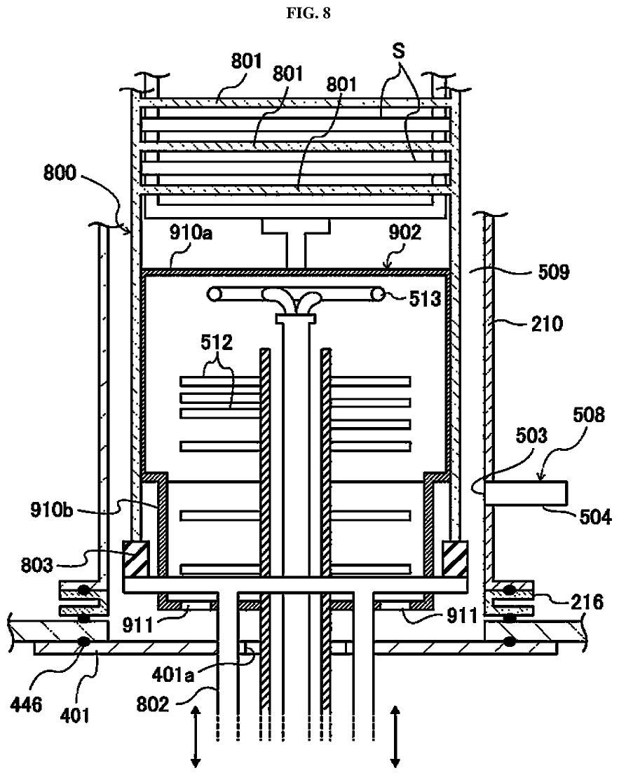

FIG. 8 is a diagram schematically illustrating a heat insulator 902 and a periphery thereof according to a third embodiment of the present disclosure.

For example, the heat insulator 902 according to the third embodiment includes a vessel 910a and a vessel 910b, and an opening 911 is provided at a bottom surface of the vessel 910b. That is, a shape of the heat insulator 902 is substantially the same as that of the heat insulator 705 according to the second embodiment described above, except that the plurality of grooves 712 are not provided on an outer side surface of the vessel 910b. Further, the exhaust hole 503 is provided beside a stepped structure (which is a connection structure connecting the vessel 910a and the vessel 910b) of the vessel 910b. Thereby, even in case where the plurality of grooves 712 are not formed, the inert gas is more likely to flow in the horizontal direction toward the exhaust hole 503. In addition, according to the present embodiment, a partition plate support 800 configured to be elevated and lowered independently of the substrate support structure 300 is provided separately. A plurality of partition plates including a partition plate 801 of a disk shape are fixed to the partition plate support 800 at a predetermined pitch therebetween. Hereafter, the plurality of partition plates including the partition plate 801 may also be simply referred to as “partition plates 801”. The partition plate support 800 is connected to a partition plate elevator (which is a partition plate elevating structure) 802. The partition plate support 800 is elevated and lowered in the vertical direction by the partition plate elevator 802. The partition plate support 800 is configured such that the partition plates 801 are interposed between the substrates S. In other words, the partition plate support 800 is configured such that a gap (distance) between the substrate S and the partition plate 801 can be adjusted up and down. Thereby, it is possible to adjust the gap between the partition plate 801 and the substrate S depending on the contents of the processing.

In the present embodiment, by adjusting the gap between the substrate S and the partition plate 801, it is possible to change a way through which the process gas flows. Thereby, it is possible to change a concentration distribution of the process gas on the surface of the substrate S. That is, the concentration distribution of the process gas on the surface of the substrate S may be changed when the distance between the surface of the substrate S and the partition plate 801 is narrowed as compared with a case where the distance between the surface of the substrate S and the partition plate 801 is widened. Therefore, by adjusting the distance between the surface of the substrate S and the partition plate 801 depending on the contents of the processing, it is possible to improve the uniformity of processing the substrate S on the surface thereof.

The partition plate support 800 and the partition plate elevator 802 are connected by a connection structure 803. The connection structure 803 is provided (disposed) between the outer side surface of the vessel 910b and the inner side surface of the reaction tube 210. That is, the connection structure 803 is disposed within a height range of the vessel 910b, which is configured to be wider than the gap between an outer side surface of the vessel 910a and the inner side surface of the reaction tube 210. The connection structure 803 may contain a metal component. However, by providing the connection structure 803 such that the connection structure 803 can be elevated and lowered within the height range of the vessel 910b in a manner described above, the inert gas flows around the connection structure 803. Thereby, it is possible to suppress the adhesion of the reaction by-products to the connection structure 803, and as a result, it is also possible to prevent the metal component contained in the connection structure 803 from flowing into the processing region A.

In addition, the third embodiment is described by way of an example in which the partition plate 801 is configured to be movable up and down relative to the substrate S. However, it is possible to obtain substantially the same effects as in the first embodiment where the substrate S is configured to be movable up and down relative to the partition plate 314.

### <Fourth Embodiment>

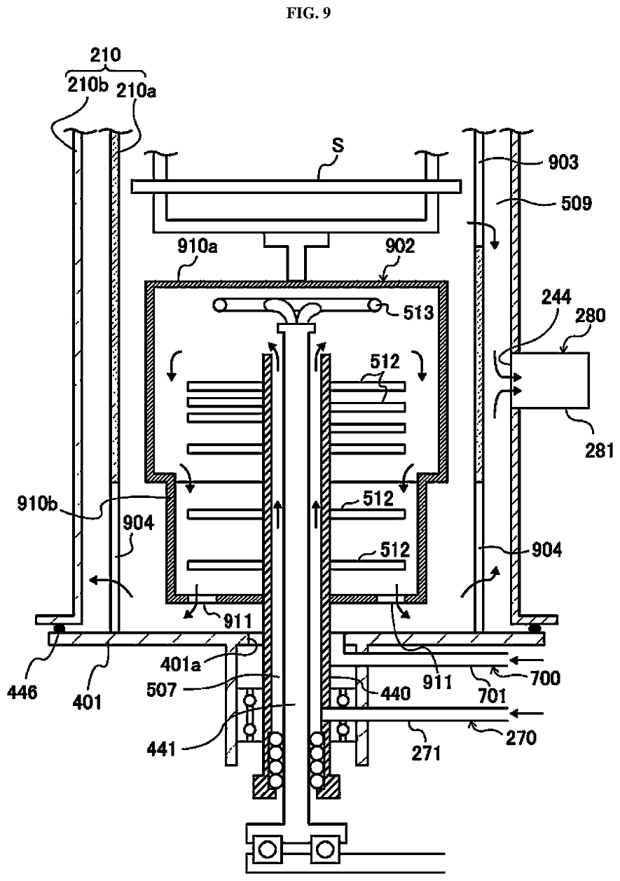

FIG. 9 is a diagram schematically illustrating a modified example (fourth embodiment) using the heat insulator 902 according to the third embodiment.

According to the fourth embodiment, the reaction tube 210 is constituted by: an inner tube 210a defining the process chamber 201; and an outer tube 210b provided in a manner concentric to the inner tube 210a and disposed outside the inner tube 210a.

An opening 903 is provided in the inner tube 210a such that a height range of the opening 903 includes a height range where the substrates S are arranged. In addition, an opening 904 serving as the first exhaust hole is provided at a lower portion of the inner tube 210a to entirely surround a height range where the vessel 910b of the heat insulator 902 extends. Further, the exhaust hole 244 is provided at the outer tube 210b at a height between the openings 903 and 904 and beside the vessel 910a.

That is, a space (also referred to as a “fourth space”) is provided at an outer periphery of the vessel 910b such that its height range includes a height range of the opening 904. The fourth space is wider than a space (also referred to as a “fifth space”) thereabove, and the inert gas supplied to the heat insulating region B from below the heat insulator 902 is more likely to flow in the horizontal direction. Since the opening 904 is provided beside the stepped structure (which is the connection structure connecting the vessel 910a and the vessel 910b) of the vessel 910b, the inert gas is more likely to flow in the horizontal direction toward the exhaust hole 244. That is, the process gas supplied to the processing region A flows through the opening 903 and then is exhausted through the exhaust hole 244. In addition, the inert gas supplied toward the subsidiary heater 513 and supplied to the heat insulating region B does not flow into the processing region A, but flows in the horizontal direction from beside the vessel 910b through the opening 904 and is exhausted through the exhaust hole 244.

For example, the embodiments mentioned above are described by way of an example in which the film is formed by using the HCDS gas as the first gas and the NH₃ gas as the second gas in the film processing step S13. However, the technique of the present disclosure is not limited thereto.

For example, the embodiments mentioned above are described by way of an example in which the first gas and the second gas are alternately supplied to the process chamber 201 and the inert gas is supplied to the heat insulating region B in accordance with the process recipe in the film processing step S13. However, the technique of the present disclosure is not limited thereto. That is, the film may be processed by simultaneously supplying the first gas and the second gas to the process chamber 201 and supplying the inert gas to the heat insulating region B.

For example, even when the film is processed using the first gas or the second gas, or using the first gas and the second gas in a plasma state, it is possible to obtain substantially the same effect as in the embodiments mentioned above.

For example, the technique of the present disclosure may also be preferably applied when the first gas is supplied without using the flash-like manner in the first gas supply (step S100) in the film processing step S13 or when the second gas is supplied in a flash-like manner (that is, a large amount of the second gas is temporarily supplied into the reaction tube 210) in the second gas supply (step S102) in the film processing step S13. Even in such a case, it is possible to obtain substantially the same effect as in the embodiments mentioned above.

For example, the embodiments mentioned above are described by way of an example in which the film forming process is performed as the substrate processing performed by the substrate processing apparatus 10. However, the technique of the present disclosure is not limited thereto. That is, instead of or in addition to the film forming process exemplified above, the technique of the present disclosure can be preferably applied even when film forming processes other than the film forming process exemplified above are performed.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses exemplified above may be substantially the same as those of the embodiments mentioned above. Even in such a case, it is possible to obtain substantially the same effects as in the embodiments mentioned above.

Further, the embodiments mentioned above may be appropriately combined. The process procedures and the process conditions of each combination thereof may be substantially the same as those of the embodiments mentioned above.

According to some embodiments of the present disclosure, it is possible to reduce the flow rate of the purge gas for purging the inside of the heat insulating structure.

What is claimed is:

1. A substrate processing apparatus comprising:
a process chamber in which a substrate is processed;
a substrate support configured to support the substrate; and
a heat insulating structure provided below the substrate support and comprising:
a vessel configured such that a horizontal cross-sectional area of an upper part of an inner space of the vessel is greater than that of a lower part of the inner space of the vessel;
a first inert gas supplier configured to be capable of supplying an inert gas into the vessel; and
an opening through which an inside and an outside of the vessel is capable of communicating with each other.

2. The substrate processing apparatus of claim 1, wherein the vessel is further configured such that the horizontal cross-sectional area of the inner space decreases stepwise along a downward direction.

3. The substrate processing apparatus of claim 1, wherein the heat insulating structure further comprises a plurality of heat insulating plates provided inside the vessel, and
wherein a distance between the vessel and one of the plurality of heat insulating plates located at a specific height is set to be shorter than a distance between the vessel and another of the plurality of heat insulating plates located at a height above the specific height.

4. The substrate processing apparatus of claim 1, further comprising:
a second inert gas supplier configured to supply the inert gas into the process chamber from below the heat insulating structure.

5. The substrate processing apparatus of claim 1, further comprising:
a first exhaust hole provided at a wall surface of the process chamber below an upper end of the heat insulating structure.

6. The substrate processing apparatus of claim 5, wherein a region configured to promote a horizontal flow of a gas existing outside the vessel at an outer periphery of the vessel is provided at the outer periphery of the vessel at a height equal to or lower than that of the first exhaust hole.

7. The substrate processing apparatus of claim 6, wherein a height range of the region comprises a height of a lowermost portion of an outer side surface of the vessel.

8. The substrate processing apparatus of claim 6, wherein a gap between an outer side surface of the vessel and an inner side surface of the process chamber in the region is set to be wider than a gap between the outer side surface of the vessel and the inner side surface of the process chamber above the region.

9. The substrate processing apparatus of claim 6, wherein a groove is provided on an outer side surface of the vessel in the region, and
wherein the groove is configured to facilitate the horizontal flow of the gas.

10. The substrate processing apparatus of claim 1, further comprising:
a heater provided in the vessel at an upper portion of the vessel.

11. The substrate processing apparatus of claim 10, wherein the first inert gas supplier is further configured to supply the inert gas toward the heater.

12. The substrate processing apparatus of claim 1, wherein the substrate support is configured to support a plurality of substrates comprising the substrate.

13. The substrate processing apparatus of claim 12, further comprising:
a plurality of gas supply holes provided respectively for the plurality of substrates and configured to supply a process gas to upper surfaces of the plurality of substrates; and
a plurality of second exhaust holes provided respectively for the plurality of substrates and configured to communicate between the process chamber and an exhauster through which a gas in the process chamber is exhausted.

14. The substrate processing apparatus of claim 12, further comprising:
a plurality of partition plates provided between each adjacent pair among the plurality of substrates; and
a partition plate support configured to support the plurality of partition plates.

15. The substrate processing apparatus of claim 14, further comprising:
a partition plate elevator configured to elevate and lower the partition plate support.

16. The substrate processing apparatus of claim 15, further comprising:
a connection structure configured to connect the partition plate support and the partition plate elevator disposed in a region located at an outer periphery of the vessel,
wherein the vessel is configured such that a gap between an outer side surface of the vessel and an inner side surface of the process chamber in the region is wider than a gap between the outer side surface of the vessel and the inner side surface of the process chamber above the region.

17. A heat insulating structure comprising:
a vessel configured such that a horizontal cross-sectional area of an upper part of an inner space of the vessel is greater than that of a lower part of the inner space of the vessel; and
an opening through which an inside and an outside of the vessel is capable of communicating with each other,
wherein an inert gas is capable of being supplied into the vessel.

18. A method of manufacturing a semiconductor device, comprising:
(a) processing a substrate in a process chamber of a substrate processing apparatus, wherein the substrate processing apparatus comprises:
the process chamber in which the substrate is processed;
a substrate support configured to support the substrate; and
a heat insulating structure provided below the substrate support and comprising:
a vessel configured such that a horizontal cross-sectional area of an upper part of an inner space of the vessel is greater than that of a lower part of the inner space of the vessel;
a first inert gas supplier configured to supply an inert gas into the vessel; and
an opening through which an inside and an outside of the vessel is capable of communicating with each other; and
(b) supplying the inert gas into the heat insulating structure and exhausting the inert gas through the opening.

19. A non-transitory computer-readable recording medium storing a program that causes a substrate processing apparatus, by a computer, to perform a process comprising the method of claim 18.
